(19) United States
(12) Patent Application Publication
(10) Pub. No.: US 2026/0227713 A1
(43) Pub. Date: Aug. 6, 2026

(54) STAGE APPARATUS, LITHOGRAPHY APPARATUS, AND ARTICLE MANUFACTURING METHOD

(71) Applicant: CANON KABUSHIKI KAISHA, Tokyo (JP)

(72) Inventor: KEN SASAKI, Kanagawa (JP)

(21) Appl. No.: 19/630,750

(22) Filed: Mar. 27, 2026

Related U.S. Application Data
(63) Continuation of application No. PCT/JP2024/036495, filed on Oct. 11, 2024.

(30) Foreign Application Priority Data
Oct. 17, 2023 (JP) 2023-179028

(51) Int. Cl. G03F 7/00

(52) U.S. Cl. CPC G03F 7/70758; G03F 7/70725; G03F 7/709

(57) ABSTRACT

A stage apparatus comprising a stage; an actuator including a mover that moves together with the stage, and a stator that generates thrust on the mover, and configured to drive the stage; a gyro moment generation unit connected to the mover; and a control unit configured to control the gyro moment generation unit such that at least a part of a moment acting on the mover when the stage is driven by the actuator is canceled by a moment generated by the gyro moment generation unit.

### CROSS-REFERENCE TO RELATED APPLICATIONS

This application is a Continuation of International Patent Application No. PCT/JP2024/036495, filed October 11, 2024, which claims the benefit of Japanese Patent Application No. 2023-179028 filed October 17, 2023, both of which are hereby incorporated by reference herein in their entirety.

### BACKGROUND

### Field of the Technology

The present invention relates to a stage apparatus, a lithography apparatus, and an article manufacturing method.

### Description of the Related Art

In a lithography apparatus represented by an exposure apparatus and an imprint apparatus, a substrate can be driven such that a shot region of the substrate is aligned with an original. In such a lithography apparatus, a stage for alignment between the substrate and the original can be driven at a high speed. However, if the stage is driven at a high speed, a moment corresponding to this is generated, and this may vibrate the stage or vibrate a floor on which the lithography apparatus is installed.

Japanese Patent Laid-Open No. 11-190786 describes a stage apparatus including a movable stage, a surface plate that supports the stage, a driving mechanism that drives the stage, and a rotor that generates a moment to reduce a reaction force generated along with the movement of the stage. Japanese Patent Laid-Open No. 2012-161896 describes a moving apparatus including a moving body, a linear motor that includes a mover attached to the moving body and that moves the mover in one axis direction, and a rotary motor fixed to the moving body. When the linear motor moves the mover, the combined moving body formed by the moving body, the mover, and the rotary motor receives a rotation torque. The rotary motor rotates a rotor to cancel at least a part of the rotation torque. However, Japanese Patent Laid-Open Nos. 11-190786 and 2012-161896 do not disclose an idea that at least a part of a moment generated when moving the mover is canceled by a gyro moment.

### SUMMARY

The present disclosure provides a technique advantageous for reducing a vibration that can be generated by driving a stage.

According to one aspect of the present disclosure, there is provided a stage apparatus comprising a stage, an actuator including a mover that moves together with the stage, and a stator that generates thrust on the mover, and configured to drive the stage, a gyro moment generation unit connected to the mover, and a control unit configured to control the gyro moment generation unit such that at least a part of a moment acting on the mover when the stage is driven by the actuator is canceled by a moment generated by the gyro moment generation unit.

Features of the present disclosure will become apparent from the following description of embodiments with reference to the attached drawings.

### BRIEF DESCRIPTION OF THE DRAWINGS

The accompanying drawings, which are incorporated in and constitute a part of the specification, illustrate embodiments of the invention and, together with the description, serve to explain principles of the invention.

FIG. 1 is a perspective view showing the configuration of a stage apparatus according to the first embodiment.

FIG. 2A is a view schematically showing the standby state of a gyro moment generation unit.

FIG. 2B is a view schematically showing the operation state of the gyro moment generation unit.

FIG. 3 is a view schematically showing a state in which a stage is driven.

FIG. 4 is a view schematically showing a configuration in which the gyro moment generation unit is connected to the lower surface of a mover.

FIG. 5 is a perspective view showing the configuration of a stage apparatus according to the second embodiment.

FIG. 6 is a view schematically showing the operation state of two gyro moment generation units.

FIG. 7 is a perspective view showing the configuration of a stage apparatus according to the third embodiment.

FIG. 8 is a perspective view in which the stage apparatus according to the third embodiment exemplifies an operation.

FIG. 9 is a view showing the configuration of an exposure apparatus according to an embodiment.

FIG. 10 is a block diagram of a control system that controls the angular velocity of a second motor.

FIG. 11 is a view schematically showing a configuration in which a gyro moment generation unit is connected to a side surface of a mover.

FIG. 12 is a view showing an example of the time-rate changes of an angular velocity ωY of the second motor of the gyro moment generation unit, an angular velocity ωZ of a first motor, and a stage moment AM.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In this specification and drawings, structures and operations will be described in accordance with an XYZ coordinate system. The Z-axis in the XYZ coordinate system can be an axis parallel to the vertical direction. Directions parallel to the X-axis, the Y-axis, and the Z-axis in the XYZ coordinate system will be referred to as the X direction, the Y direction, and the Z direction, respectively.

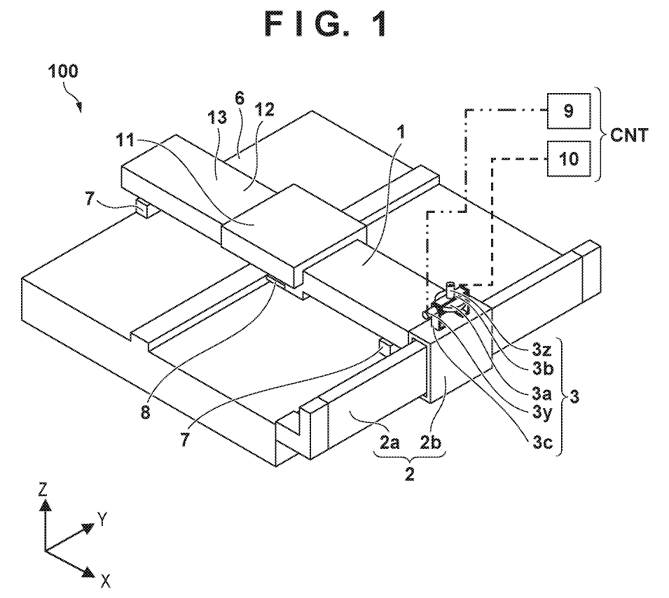

FIG. 1 is a perspective view showing the configuration of a stage apparatus 100 according to the first embodiment. The stage apparatus 100 can be used as, for example, the stage apparatus of a lithography apparatus (pattern transfer apparatus) such as an exposure apparatus or an imprint apparatus. The stage apparatus 100 includes an X driving unit 12 and a Y driving unit 1, which drive a stage (movable table) 11 in the X direction and the Y direction, respectively. The Y driving unit 1 is restricted concerning the Z direction by a pressure applying mechanism (not shown) formed by a Z air jetting unit 7 forming an air bearing, and a magnet arranged near it. A pressure applying mechanism including an X air jetting unit 8 has a similar configuration and restricts the Y driving unit 1 concerning the X direction. Hence, the Y driving unit 1 is guided in a noncontact state by a surface plate 6 via the Z air jetting unit 7 and the X air jetting unit 8 and can move only in the Y direction. The Y driving unit 1 is driven in the Y direction by a linear motor 2 (actuator) formed by a stator 2a and a mover 2b. The stage 11 is arranged on the Y driving unit 1 and moves in the Y direction together with the Y driving unit 1. That is, the stator 2a generates thrust on the mover 2b in the Y direction, and the mover 2b moves in the Y direction together with the stage 11.

The X driving unit 12 drives the stage 11 in the X direction along the Y driving unit 1 by a linear motor formed by a stator 13 and a mover (not shown). The stage 11 is provided with an X encoder (not shown) that measures the X-direction position of the stage 11. The Y driving unit 1 is provided with a Y encoder (not shown) that measures the Y-direction position of the stage 11. The stage 11 can be controlled to be driven or positioned to an arbitrary target position based on the X- and Y-direction positions of the stage 11 measured by the X encoder and the Y encoder.

A gyro moment generation unit 3 can be mounted on the mover 2b. In the example shown in FIG. 1, the gyro moment generation unit 3 is connected to the upper surface of the mover 2b. The gyro moment generation unit 3 can include a rotating body 3a, a first gimbal 3b, a first motor 3z, a second gimbal 3c, and a second motor 3y. The first gimbal 3b supports the rotating body 3a such that it can rotate about a second axis (Z-axis) perpendicular to a first axis (Y-axis). The first axis can be a fixed axis parallel to the Y-axis. The second axis can be an axis parallel to the Z-axis in the standby state but can be an axis that is rotated about the first axis (Y-axis) in an operation state. The first motor 3z rotates the rotating body 3a about the second axis. The second gimbal 3c supports the first gimbal 3b (rotating body 3a) such that it can rotate about the first axis. The second motor 3y rotates the first gimbal 3b (rotating body 3a) about the first axis, and the second axis also rotates about the first axis accordingly.

The stage apparatus 100 can include a control unit CNT that controls the gyro moment generation unit 3. When the stage 11 is driven by the linear motor 2, a moment can act on the mover 2b (and all constituent elements that move together with the mover 2b). This moment will be referred to as a stage moment hereinafter. The control unit CNT can control the gyro moment generation unit 3 such that at least a part of the stage moment is canceled by the moment generated by the gyro moment generation unit 3. The control unit CNT can include a first motor control unit 10 and a second motor control unit 9. The first motor control unit 10 controls the rotation (angular velocity) of the first motor 3z, and the second motor control unit 9 controls the rotation (angular velocity) of the second motor 3y.

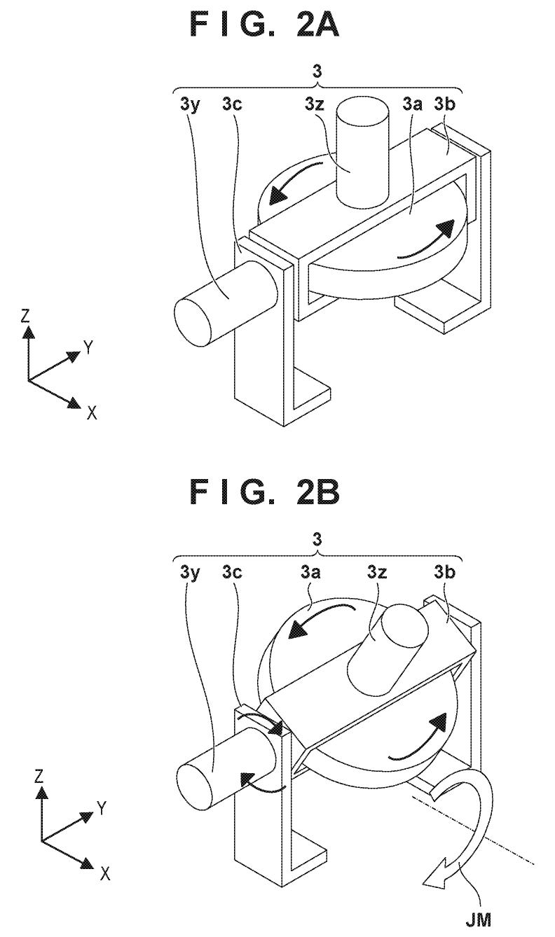

Next, the principle by which the gyro moment generation unit 3 generates a gyro moment JM will be described. FIG. 2A schematically shows the standby state of the gyro moment generation unit 3, and FIG. 2B schematically shows the operation state of the gyro moment generation unit 3. In the standby state, the first motor 3z rotates the rotating body 3a about the second axis (the Z-axis in FIG. 2A) at a predetermined angular velocity. In the operation state, while the first motor 3z keeps rotating the rotating body 3a about the second axis at the predetermined angular velocity, the second motor 3y rotates the rotating body 3a (first gimbal 3b) about the first axis (Y-axis). The gyro moment generation unit 3 thus generates the gyro moment JM about the X-axis. From the viewpoint of reducing power consumption, the first motor control unit 10 or the control unit CNT may stop the rotation of the first motor 3z if the gyro moment JM need not be generated.

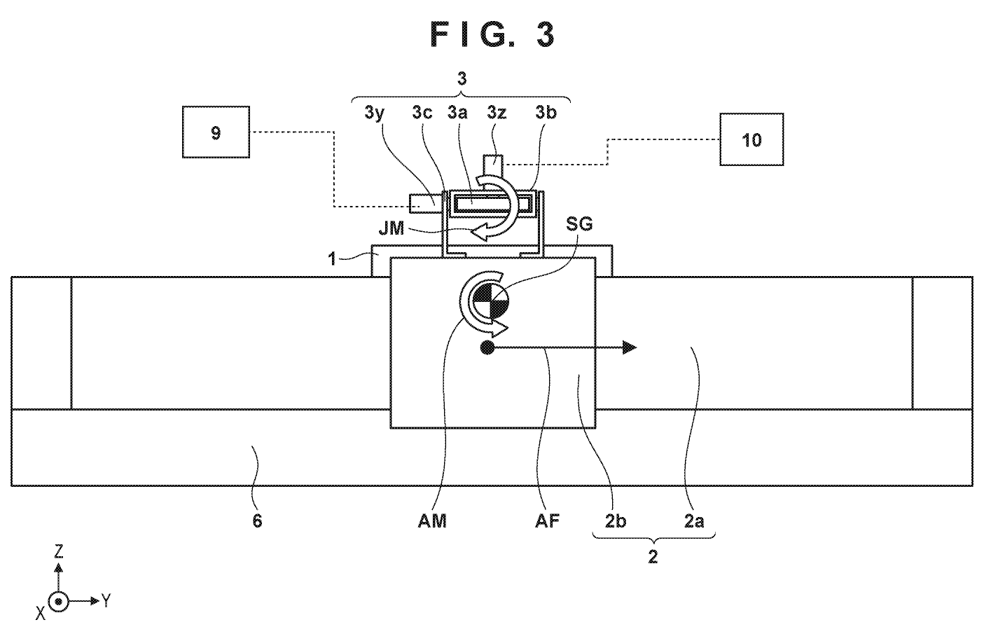

FIG. 3 schematically shows a state in which the Y driving unit 1 is driven in the Y direction by the linear motor 2. The generation principle of a stage moment AM that is generated in a movable portion when the Y driving unit 1 is driven in the Y direction will be described. Here, the movable portion means the aggregate of all constituent elements that move together with the mover 2b and, more specifically, includes the Y driving unit 1, the X driving unit 12, the stage 11, and the gyro moment generation unit 3. To move the Y driving unit 1 in the Y direction, a thrust AF is generated for the mover 2b. Since the action position of the thrust AF and a gravity center (to be referred to as a stage gravity center hereinafter) SG of the movable portion deviate in the Z direction, the stage moment AM is generated about the X-axis.

The generation principle of the gyro moment JM is as described above, and the gyro moment JM is generated by rotating the rotating body 3a, which is rotating about the first axis (Y-axis) at a predetermined angular velocity, about the first axis (Y-axis). The control unit CNT can activate the gyro moment generation unit 3 before the linear motor 2 starts driving the stage 11 (before the linear motor 2 generates a thrust). More specifically, the first motor control unit 10 can activate the first motor 3z and rotate the rotating body 3a at a predetermined angular velocity before driving of the stage 11 is started (before the linear motor 2 is caused to generate a thrust). In addition, the second motor control unit 9 can control the angular velocity of the second motor 3y to generate the gyro moment JM having the same magnitude as the stage moment AM but an opposite direction.

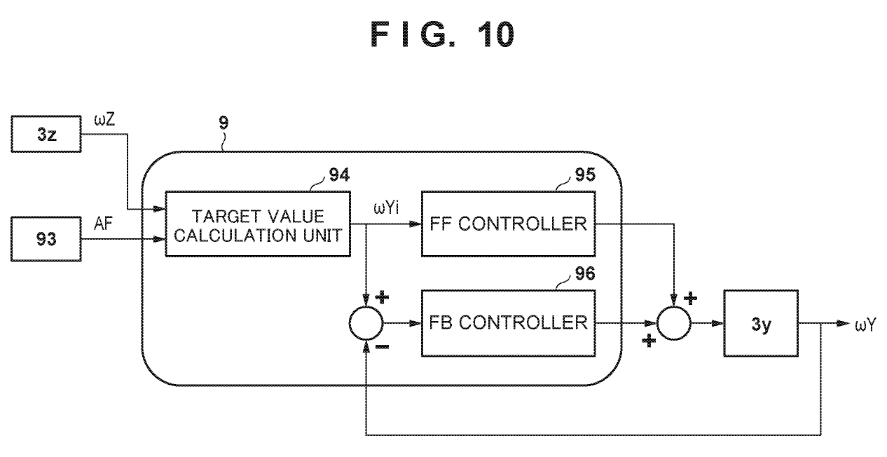

FIG. 10 is a block diagram of a control system that controls the angular velocity of the second motor 3y. The second motor control unit 9 can include a target value calculation unit 94, a feedforward (FF) controller 95, and a feedback (FB) controller 96. The target value calculation unit 94 can calculate a target angular velocity ωYi such that JM = AM is satisfied. More specifically, the target value calculation unit 94 can calculate the target angular velocity ωYi in accordance with ωYi = AM/(IZ × ωZ). The stage moment AM can be calculated by multiplication of the magnitude of the thrust AF and the distance between the stage gravity center SG and the action position (Z direction) of the thrust AF. The magnitude of the thrust AF can be calculated by multiplication of the driving current of the linear motor 2 and the thrust constant of the linear motor 2. The driving current can be obtained from a linear motor control unit 93. The thrust constant of the linear motor 2 and the distance between the stage gravity center SG and the action position (Z direction) of the thrust AF can be calculated from design values. IZ indicates the inertial moment of the rotating body 3a about the second axis (Z-axis) and can be calculated from the design value of the rotating body 3a. ωZ indicates the predetermined angular velocity of the rotating body 3a about the second axis (Z-axis) and can be obtained from an encoder (not shown) incorporated in the first motor 3z.

To reduce the deviation between the target angular velocity ωYi and an angular velocity ωY of the second motor 3y, the FB controller 96 gives a feedback operation amount to the motor 3y. The angular velocity ωY of the second motor 3y can be obtained from an encoder (not shown) incorporated in the second motor 3y. The FF controller 95 can feedforward-control the second motor 3y while giving a feedforward operation amount calculated from the target angular velocity ωYi to the second motor 3y. That is, the second motor control unit 9 (control unit CNT) can feedforward-control the second motor 3y based on control information (for example, the thrust AF to be generated by the linear motor 2 or the current supplied to the linear motor 2) for controlling the linear motor 2.

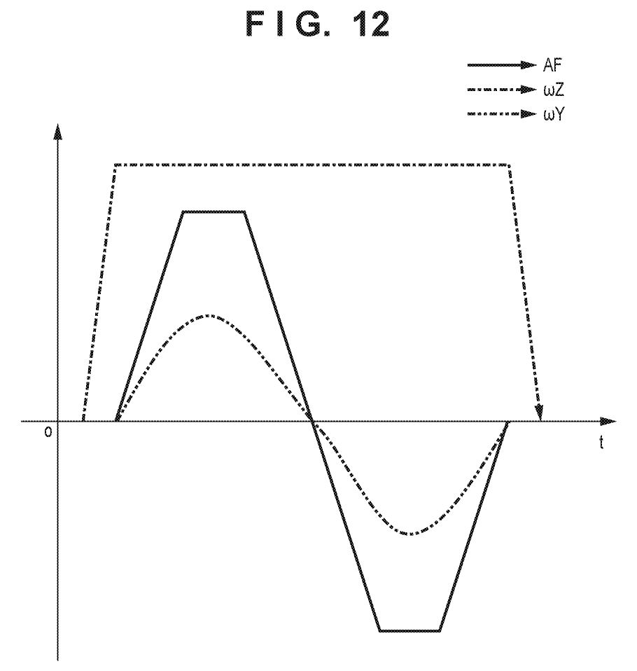

As described above, the second motor control unit 9 (control unit CNT) controls the angular velocity of the second motor 3y at the same time as the driving of the linear motor 2 and generates the gyro moment JM at the same time as the generation of the stage moment AM. This can cancel the whole stage moment AM about the X-axis without a time delay. Note that the target angular velocity ωYi may be generated to cancel at least a part of the stage moment AM. FIG. 12 shows an example of the time-rate changes of the angular velocity ωY, the angular velocity ωZ, and the stage moment AM.

The gyro moment JM is represented by IZ × ωZ × ωY. Hence, the magnitude of the gyro moment JM is determined independently of the position of the stage gravity center SG. This means even in a case where the position of the stage gravity center SG has individual differences, the stage moment AM can correctly be canceled.

After the stage moment AM about the X-axis is canceled, the second motor control unit 9 controls the second motor 3y such that the rotating body 3a returns to the position before the cancellation. At this time, not to generate the gyro moment JM, the first motor control unit 10 preferably controls the first motor 3z such that the angular velocity of the first motor 3z is 0.

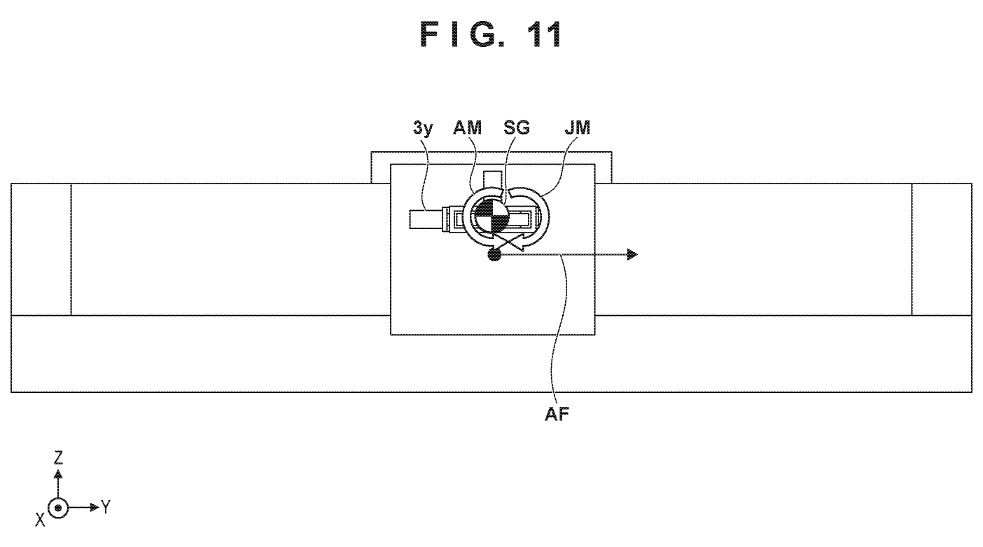

In the example shown in FIG. 1, the gyro moment generation unit 3 is connected to the upper surface of the mover 2b. However, the present invention is not limited to this. For example, as exemplified in FIG. 11, the gyro moment generation unit 3 may be connected to a side surface of the mover 2b. In the example shown in FIG. 11, the position of the stage gravity center SG in the Z direction and the position of the driving shaft of the second motor 3y of the gyro moment generation unit 3 in the Z direction match. This can make the action position of the stage moment AM match the action position of the gyro moment JM. This arrangement is advantageous for suppressing a twisting moment applied to the mover 2b and reducing a vibration generated by the twisting moment.

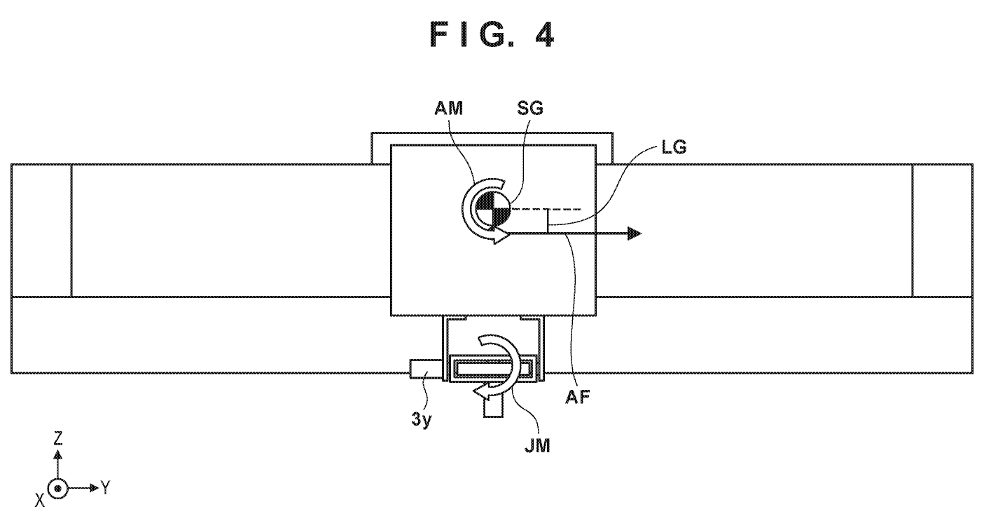

As exemplified in FIG. 4, the gyro moment generation unit 3 may be connected to the lower surface of the mover 2b. In the example shown in FIG. 4, as compared to the example shown in FIG. 1, the position of the stage gravity center SG can be moved to the negative side in the Z direction. This can make a distance LG between the stage gravity center SG and the action position of the thrust AF short and make the magnitude of the stage moment AM small. This arrangement is advantageous for making the magnitude of the gyro moment JM small and reducing the power consumption of the second motor 3y.

In this embodiment, an example in which a linear motor is employed as an actuator that drives the Y driving unit 1 is shown. However, for example, a ball screw and a servo motor may be employed as an actuator. In this case, it is excellent in terms of cost.

In this embodiment, an example in which a pressure applying mechanism formed by an air jetting unit forming an air bearing and a magnet is employed to restrict the Y driving unit 1 is shown, but a slider and a guide may be used instead. In this case, it is excellent in terms of cost.

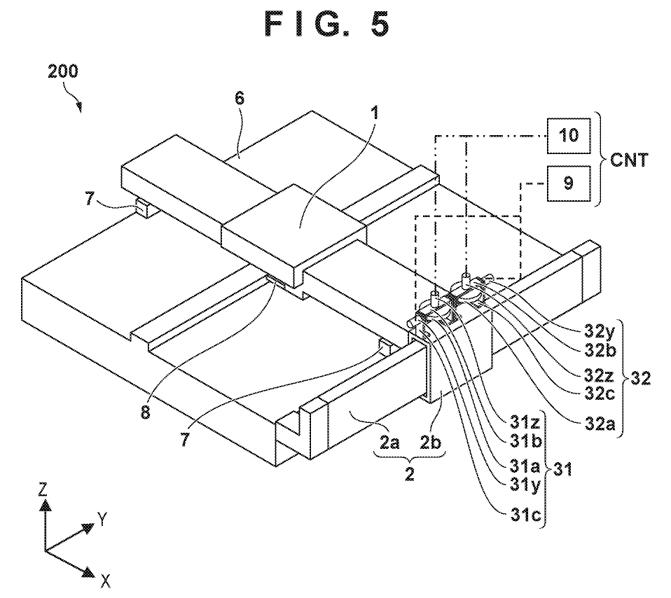

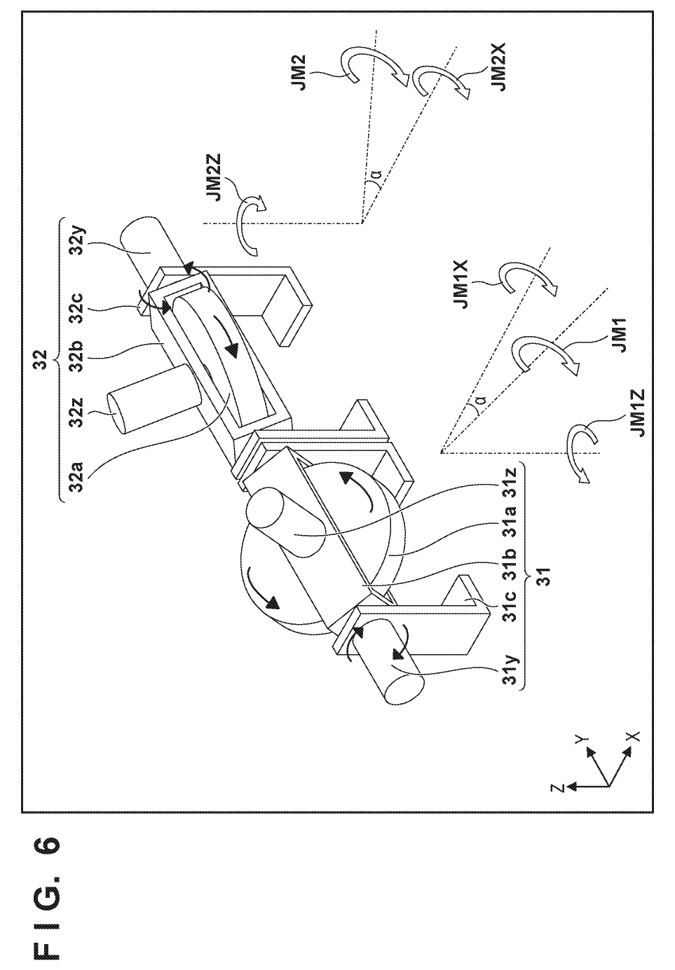

A stage apparatus 200 according to the second embodiment will be described below with reference to FIGS. 5 and 6. Matters that are not mentioned in the second embodiment can comply with the first embodiment. FIG. 5 is a perspective view showing the configuration of the stage apparatus 200 according to the second embodiment. The second embodiment provides the stage apparatus 200 including a plurality of gyro moment generation units 31 and 32.

In the example shown in FIG. 5, the stage apparatus 200 includes the two gyro moment generation units 31 and 32. The gyro moment generation units 31 and 32 each have the same configuration as the gyro moment generation unit 3 according to the first embodiment. To distinguish the gyro moment generation units 31 and 32, these may be referred to as first and second gyro moment generation units 31 and 32. The gyro moment generation units 31 and 32 that are the plurality of gyro moment generation units are connected to a mover 2b.

When a stage 11 is driven by a linear motor 2, a stage moment acts on the mover 2b. A control unit CNT controls the first and second gyro moment generation units 31 and 32 such that at least a part of the stage moment is canceled by moments generated by the gyro moment generation units 31 and 32. The first and second gyro moment generation units 31 and 32 can be aligned along a first direction (Y direction) parallel to the first axis (Y-axis).

The first gyro moment generation unit 31 can include a first rotating body 31a, a first gimbal 31b, a first motor 31z, a second gimbal 31c, and a second motor 31y. The first rotating body 31a, the first gimbal 31b, the first motor 31z, the second gimbal 31c, and the second motor 31y can have the same configurations as the rotating body 3a, the first gimbal 3b, the first motor 3z, the second gimbal 3c, and the second motor 3y of the first embodiment, respectively. The second gyro moment generation unit 32 can include a second rotating body 32a, a third gimbal 32b, a third motor 32z, a fourth gimbal 32c, and a fourth motor 32y. The second rotating body 32a, the third gimbal 32b, the third motor 32z, the fourth gimbal 32c, and the fourth motor 32y can have the same configurations as the rotating body 3a, the first gimbal 3b, the first motor 3z, the second gimbal 3c, and the second motor 3y of the first embodiment, respectively.

FIG. 6 shows the operation state of the first and second gyro moment generation units 31 and 32. The gyro moment generation principle and the method of calculating the angular velocities of the second and fourth motors 31y and 32y are the same as in the first embodiment. In the second embodiment, however, since the first and second gyro moment generation units 31 and 32 are provided, the angular velocities of the second and fourth motors 31y and 32y can have a magnitude about 1/2 the angular velocity of the second motor 3y of the first embodiment. As shown in FIG. 6, the angular velocities of the first and second rotating bodies 31a and 32a rotated by the first and third motors 31z and 32z have the same magnitude, but the rotation directions of the first and second rotating bodies 31a and 32a rotated by the first and third motors 31z and 32z are different. Hence, since the moment generated at the time of driving of the first motor 31z and the moment generated at the time of driving of the third motor 32z cancel each other, generation of moments about the Y-axis and the Z-axis is suppressed. Similarly, since the moments generated by the second and fourth motors 31y and 32y at the time of driving cancel each other, generation of the moment about the Y-axis is also suppressed. That is, by providing the first and second gyro moment generation units 31 and 32, generation of the moments about the Z-axis and the Y-axis, which are generated at the time of driving of the first and third motors 31z and 32z and the second and fourth motors 31y and 32y, is suppressed.

When the first and second gyro moment generation units 31 and 32 are operated, gyro moments JM1 and JM2 are generated. Let α be the angle made by the driving shaft of the first and third motors 31z and 32z and the Z-axis. The gyro moment JM1 can be decomposed to a θX gyro moment JM1X acting about the X-axis and a θZ gyro moment JM1Z acting about the Z-axis. The gyro moment JM2 can similarly be decomposed to a θX gyro moment JM2X and a θZ gyro moment JM2Z. The magnitudes of these can be expressed as JM1X = JM1 × cosα, JM2X = JM2 × cosα, JM1Z = JM1 × sinα, and JM2Z = JM2 × sinα. Since the gyro moment JM1 and the gyro moment JM2 have the same magnitude, the θX gyro moment JM1X and the θX gyro moment JM2X are moments having the same magnitude and opposite directions, and cancel each other. Hence, the magnitude of the moment generated by the gyro moment generation units 31 and 32 is JM1X + JM2X. It is therefore possible to generate a moment only about the X-axis independently of the angle α.

The moment about the X-axis generated by the first and second gyro moment generation units 31 and 32 is expressed as (JM1 + JM2) × cosα, and this is maximized when the angle α is 0° (cosα = 1). Hence, the postures of the first and second rotating bodies 31a and 32a in a standby state are preferably controlled by the second and fourth motors 31y and 32y such that the angle α is 0° when the magnitude of the stage moment generated at the time of driving of the linear motor 2 is maximized. In addition, when the angle α is 90° or -90°, the θX gyro moments JM1X and JM2X are 0 and, therefore, the moment about the X-axis is not generated. Hence, the second and fourth motors 31y and 32y can be controlled such that α is more than -90° and less than 90°.

As a detailed example, an example in which two gyro moment generation units are provided has been described here. However, three or more gyro moment generation units may be provided. In this case, the angular velocity of the motor that rotates the rotating body about the Y-axis and the angular velocity of the motor that rotates the rotating body about the Z-axis can be controlled such that the moments generated about the Y-axis and the Z-axis are canceled. According to this configuration, it is possible to reduce the size of each gyro moment generation unit and improve the degree of freedom of design of the stage apparatus.

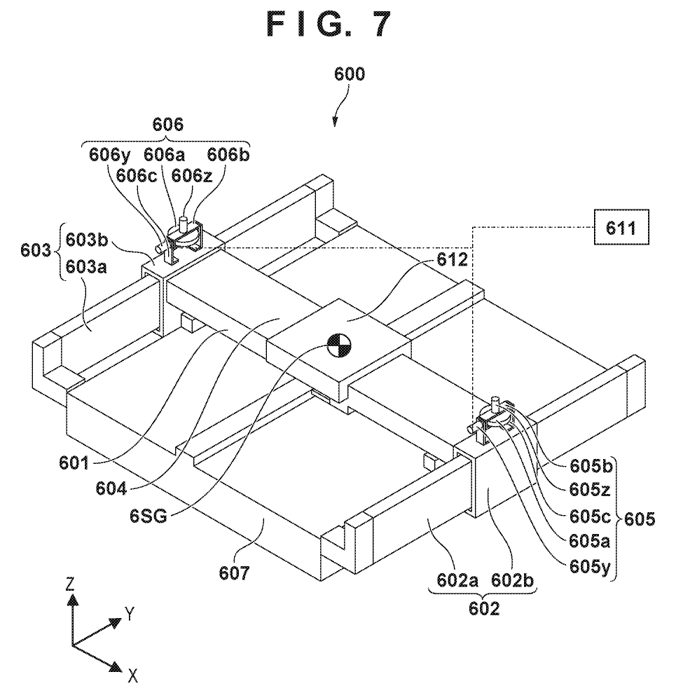

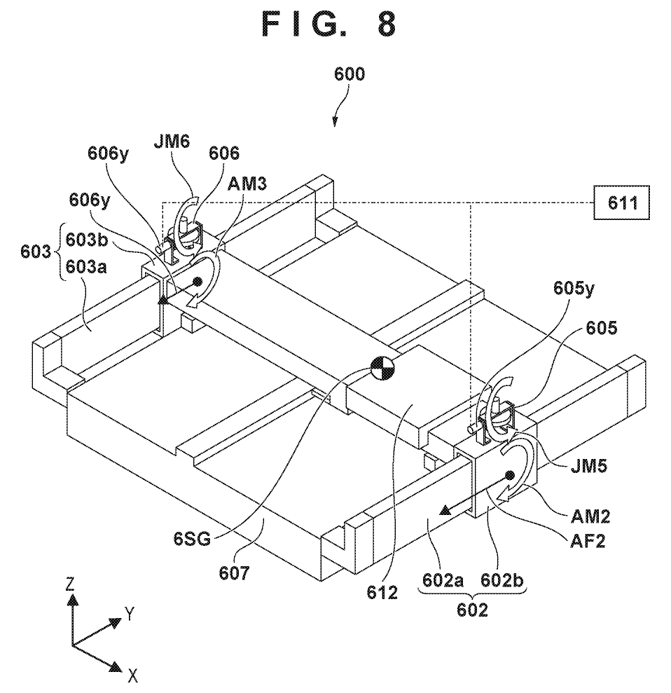

A stage apparatus 600 according to the third embodiment will be described below with reference to FIGS. 7 and 8. Matters that are not mentioned in the third embodiment can comply with the first embodiment. FIG. 7 is a perspective view showing the configuration of the stage apparatus 600 according to the third embodiment. The third embodiment provides the stage apparatus 600 including a plurality of gyro moment generation units 605 and 606 and a plurality of linear motors 602 and 603.

The stage apparatus 600 can additionally include a stage 612, an X driving unit 604, and a Y driving unit 601. The stage 612 can be driven or positioned to an arbitrary target position by driving the X driving unit 604 in the X direction and driving the Y driving unit 601 in the Y direction.

As actuators that drive the Y driving unit 601 in the Y direction, the linear motors 602 and 603 can be provided. The linear motor 602 includes a mover 602b and a stator 602a. The linear motor 603 includes a mover 603b and a stator 603a. The gyro moment generation units 605 and 606 can be provided on the movers 602b and 603b, respectively. The gyro moment generation units 605 and 606 can have the same configuration as the gyro moment generation unit 3 according to the first embodiment. To distinguish the gyro moment generation units 605 and 606 from one another, these may be referred to as first and second gyro moment generation units 605 and 606. Each of the first and second gyro moment generation units 605 and 606 can be connected to a corresponding one of the movers 602b and 603b.

When the stage 612 is driven by the linear motors 602 and 603, a stage moment acts on the movers 602b and 603b. A control unit CNT controls the first and second gyro moment generation units 605 and 606 such that at least a part of the stage moment is canceled by moments generated by the first and second gyro moment generation units 605 and 606.

The first gyro moment generation unit 605 can include a first rotating body 605a, a first gimbal 605b, a first motor 605z, a second gimbal 605c, and a second motor 605y. The first rotating body 605a, the first gimbal 605b, the first motor 605z, the second gimbal 605c, and the second motor 605y can have the same configurations as the rotating body 3a, the first gimbal 3b, the first motor 3z, the second gimbal 3c, and the second motor 3y of the first embodiment, respectively. The second gyro moment generation unit 606 can include a second rotating body 606a, a third gimbal 606b, a third motor 606z, a fourth gimbal 606c, and a fourth motor 606y. The second rotating body 606a, the third gimbal 606b, the third motor 606z, the fourth gimbal 606c, and the fourth motor 606y can have the same configurations as the rotating body 3a, the first gimbal 3b, the first motor 3z, the second gimbal 3c, and the second motor 3y of the first embodiment, respectively.

FIG. 8 schematically shows a state in which the stage 612 is located in the positive direction of the X-axis, as compared to FIG. 7, and the stage 612 is driven in the Y-axis direction in this state. In a state in which the stage 612 is located in the positive direction of the X-axis, the distance between a stage gravity center 6SG and the thrust action position of the linear motor 602 in the X direction is shorter than the distance between the stage gravity center 6SG and the thrust action position of the linear motor 603 in the X direction. When driving the stage 612 in the Y direction in this state, to suppress a moment about the Z-axis acting on the Y driving unit 601, the linear motors 602 and 603 are caused to generate different thrusts AF2 and AF3. Hence, stage moments AM2 and AM3 about the X-axis generated by the distance between the stage gravity center 6SG and the action position of the thrust AF2 in the Z direction and the positional deviation between the stage gravity center 6SG and the action position of the thrust AF3 in the Z direction have different magnitudes.

A second motor control unit 611 can control the angular velocity of the second motor 605y such that a gyro moment JM5 generated by the gyro moment generation unit 605 has the same magnitude as the stage moment AM2 and an opposite direction. The gyro moment generation principle and the method of calculating the angular velocity are the same as in the first embodiment. As for the gyro moment generation unit 606 as well, the second motor control unit 611 can control the angular velocity of the fourth motor 606y such that a gyro moment JM6 has the same magnitude as the stage moment AM3 and an opposite direction. This makes it possible to cancel the moment about the X-axis at each moment generation position and cancel the moment without generating a twisting moment in the Y driving unit 601. It is therefore possible to suppress a vibration of a surface plate 607 caused by twist of the Y driving unit 601.

A lithography apparatus to which the stage apparatus represented by the first to third embodiments is applied will be described below. The lithography apparatus can be configured to transfer the pattern of an original to a substrate, and the stage apparatus can be configured to align the original and the substrate. If the lithography apparatus is an exposure apparatus, the stage apparatus may be applied as a substrate stage apparatus, may be applied as an original stage apparatus, or may be applied as a substrate stage apparatus and an original stage apparatus. If the lithography apparatus is an imprint apparatus, the stage apparatus can be applied as a substrate stage apparatus.

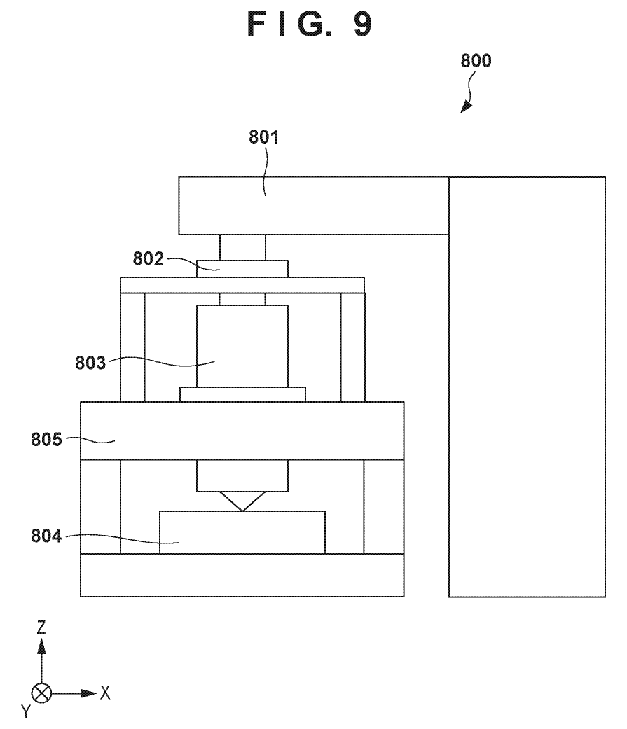

FIG. 9 exemplarily shows the configuration of an exposure apparatus 800 according to an embodiment. The exposure apparatus 800 can include, for example, an illumination optical system 801, an original stage apparatus 802 that positions an original, a projection optical system 803, and a substrate stage apparatus 804 that positions a substrate. The exposure apparatus 800 can be configured to transfer the pattern of the original to the substrate. The exposure apparatus 800 can be configured to transfer the pattern of the original to the substrate by a step-and-repeat method or a step-and-scan method.

The illumination optical system 801 can be configured to include a light source unit and an illumination optical system and illuminate the original. The light source unit can include, for example, a laser. As the laser, an ArF excimer laser with a wavelength of about 193 nm, a KrF excimer laser with a wavelength of about 248 nm, or the like can be used. The type of the laser is not limited to the excimer laser and, for example, a YAG laser may be used, and the number of lasers is not limited. If a laser is used in the light source unit, it is preferable to use a light beam shaping optical system that shapes a parallel light beam from the laser light source into a desired beam shape or an incoherent optical system that makes a coherent laser beam incoherent. The light source usable in the light source unit is not limited to a laser, and one or a plurality of lamps such as mercury lamps or xenon lamps can also be used. Also, the light source unit may include an EUV light source.

As the projection optical system 803, an optical system including only a plurality of lens elements, an optical system forming a plurality of lens elements and at least one concave mirror, an optical system comprising a plurality of lens elements and at least one diffractive optical element, or an all-reflective optical system can be used.

A stage apparatus represented by the above-described embodiments can be applied to at least one of the original stage apparatus 802 and the substrate stage apparatus 804. In the step-and-scan method, the stage of the original stage apparatus 802 and the stage of the substrate stage apparatus 804 are driven in synchronism. The exposure apparatus 800 can be used to manufacture, for example, a semiconductor device such as a semiconductor integrated circuit and a device with a fine pattern formed such as a micromachine or a thin film magnetic head.

An article manufacturing method of manufacturing an article using the above-described lithography apparatus will exemplarily be described below. The article manufacturing method can include a transfer step of transferring a pattern of an original to a substrate using the above-described lithography apparatus, and a processing step of processing the substrate that has undergone the transfer step, thereby obtaining an article.

If the lithography apparatus is an exposure apparatus, a substrate to which a photosensitive material is applied is used, and the pattern of the original can be transferred as a latent image to the photosensitive material of the substrate by the transfer step. The processing step can include a developing step of converting the latent image into a physical pattern. The processing step can also include a step of processing (for example, etching) the substrate using the physical pattern formed by the developing step.

If the lithography apparatus is an imprint apparatus, in the transfer step, an imprint material is applied to the substrate, and the pattern of the original is transferred to the imprint material. The processing step can include a step of processing (for example, etching) the substrate using the pattern transferred to the imprint material.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

1. A stage apparatus comprising:
a stage;
an actuator including a mover that moves together with the stage, and a stator that generates thrust on the mover, and configured to drive the stage;
a gyro moment generation unit connected to the mover; and
a control unit configured to control the gyro moment generation unit such that at least a part of a moment acting on the mover when the stage is driven by the actuator is canceled by a moment generated by the gyro moment generation unit.

2. The stage apparatus according to claim 1, wherein:
the gyro moment generation unit includes;
a first gimbal configured to support a rotating body such that the rotating body can rotate about a second axis perpendicular to a first axis parallel to a direction in which the actuator drives the stage;
a first motor configured to rotate the rotating body about the second axis;
a second gimbal configured to support the first gimbal such that the first gimbal can rotate about the first axis; and
a second motor configured to rotate the first gimbal about the first axis.

3. The stage apparatus according to claim 2, wherein:
the control unit feedforward-controls the second motor based on control information for controlling the actuator.

4. The stage apparatus according to claim 3, wherein:
the control information includes a thrust to be generated by the actuator.

5. The stage apparatus according to claim 3, wherein:
the control information includes a current to be supplied to the actuator.

6. The stage apparatus according to claim 1, further comprising
a surface plate, and a driving unit connected to the mover to be moved on the surface plate,
wherein the stage moves together with the driving unit on the surface plate.

7. The stage apparatus according to claim 6, wherein:
the gyro moment generation unit is connected to an upper surface of the mover.

8. The stage apparatus according to claim 6, wherein:
the gyro moment generation unit is connected to a side surface of the mover.

9. The stage apparatus according to claim 6, wherein:
the gyro moment generation unit is connected to a lower surface of the mover.

10. The stage apparatus according to claim 1, further comprising
a plurality of gyro moment generation units including the gyro moment generation unit,
wherein the plurality of gyro moment generation units are connected to the mover, and
the control unit controls the plurality of gyro moment generation units such that at least a part of the moment acting on the mover when the stage is driven by the actuator is canceled by moments generated by the plurality of gyro moment generation units.

11. The stage apparatus according to claim 10, wherein:
the plurality of gyro moment generation units are aligned along the direction in which the actuator drives the stage.

12. The stage apparatus according to claim 2, further comprising
a second gyro moment generation unit connected to the mover,
wherein the gyro moment generation unit and the second gyro moment generation unit are aligned along the direction in which the actuator drives the stage,
the second gyro moment generation unit includes:
a third gimbal configured to support a second rotating body such that the second rotating body can rotate about the second axis;
a third motor fixed and configured to rotate the second rotating body about the second axis;
a fourth gimbal configured to support the third gimbal such that the third gimbal can rotate about the first axis; and
a fourth motor configured to rotate the fourth gimbal about the first axis,
a direction in which the first motor rotates the rotating body in the gyro moment generation unit and a direction in which the third motor rotates the second rotating body in the second gyro moment generation unit are opposite each other, and
a direction in which the second motor rotates the rotating body in the gyro moment generation unit and a direction in which the fourth motor rotates the second rotating body in the second gyro moment generation unit are opposite each other.

13. The stage apparatus according to claim 1, further comprising:
a plurality of gyro moment generation units including the gyro moment generation unit; and
a plurality of actuators including the actuator,
wherein each of the plurality of actuators includes a mover that moves together with the stage, and a stator that generates a thrust on the mover, and
each of the plurality of gyro moment generation units is connected to the mover of a corresponding one of the plurality of actuators.

14. The stage apparatus according to claim 13, wherein:
the control unit feedforward-controls each of the plurality of gyro moment generation units based on control information for controlling a corresponding one of the plurality of actuators.

15. The stage apparatus according to claim 1, wherein:
the control unit activates the gyro moment generation unit before the actuator starts driving the stage.

16. A lithography apparatus for transferring a pattern of an original to a substrate, comprising a stage apparatus configured to align the original with the substrate, wherein the stage apparatus comprises:
a stage;
an actuator including a mover that moves together with the stage, and a stator that generates thrust on the mover, and configured to drive the stage;
a gyro moment generation unit connected to the mover; and
a control unit configured to control the gyro moment generation unit such that at least a part of a moment acting on the mover when the stage is driven by the actuator is canceled by a moment generated by the gyro moment generation unit.

17. An article manufacturing method comprising:
a transfer step of transferring a pattern of an original to a substrate using a lithography apparatus; and
a processing step of processing the substrate that has undergone the transfer step, thereby obtaining an article,
wherein the lithography apparatus comprises a stage apparatus which is configured to align the original with the substrate and comprises:
a stage;
an actuator including a mover that moves together with the stage, and a stator that generates thrust on the mover, and configured to drive the stage;
a gyro moment generation unit connected to the mover; and
a control unit configured to control the gyro moment generation unit such that at least a part of a moment acting on the mover when the stage is driven by the actuator is canceled by a moment generated by the gyro moment generation unit.
